(19) United States
(12) Patent Application Publication
(10) Pub. No.: US 2018/0138394 A1
(43) Pub. Date: May 17, 2018

(54) PIEZOELECTRIC ELEMENT, PIEZOELECTRIC ELEMENT APPLICATION DEVICE, AND METHOD OF MANUFACTURING PIEZOELECTRIC ELEMENT

(71) Applicant: Seiko Epson Corporation, Tokyo (JP)

(72) Inventor: Kazuya KITADA, Suwa (JP)

(21) Appl. No.: 15/800,652

(22) Filed: Nov. 1, 2017

(30) Foreign Application Priority Data
Nov. 15, 2016 (JP) 2016-222727

(51) Int. Cl. H01L 41/18; H01L 41/047; H01L 41/08; H01L 41/29; H01L 41/319; B41J 2/14; B41J 2/16

(52) U.S. Cl. CPC H01L 41/18; H01L 41/0477; H01L 41/0815; H01L 41/29; H01L 41/332; B41J 2/14233; B41J 2/161; B41J 2/164; H01L 41/319

(57) ABSTRACT

A piezoelectric element includes a first electrode, a piezoelectric layer formed on the first electrode by a solution method and formed of a perovskite-type composite oxide including potassium, sodium, and niobium, and a second electrode provided on the piezoelectric layer, in which the composite oxide further includes lithium and manganese, the content of lithium is 3 mol % to 5 mol % in the total number of moles of metal in the A site, the content of manganese is 5 mol % or less in the total number of moles of metal in the B site, and a lithium measured intensity (CPS) maximum value in the film thickness direction of the piezoelectric layer in SIMS measurement is less than 2.65 times a minimum value.

This application claims priority under 35 U.S.C. § 119 to Japanese Patent Application No. 2016-222727 filed on Nov. 15, 2016, the entire disclosure of which is expressly incorporated by reference herein.

### BACKGROUND

### 1. Technical Field

The present invention relates to a piezoelectric element provided with a first electrode, a piezoelectric layer, and a second electrode, a piezoelectric element application device provided with a piezoelectric element, and a method for manufacturing a piezoelectric element.

### 2. Related Art

In general, piezoelectric elements have a piezoelectric layer which has electro-mechanical conversion characteristics, and two electrodes with the piezoelectric layer interposed therebetween. In recent years, devices (piezoelectric element application devices) using such piezoelectric elements as a driving source have been actively developed. As a piezoelectric element application device, there are liquid ejecting heads which are represented by an ink jet recording head, MEMS elements which are represented by a piezoelectric MEMS element, ultrasonic measuring apparatuses which are represented by an ultrasonic sensor or the like, as well as piezoelectric actuator apparatuses, and the like.

Lead zirconate titanate (PZT) is known as a material (piezoelectric material) of a piezoelectric layer of a piezoelectric element; however, from the viewpoint of reducing the environmental impact, lead-free piezoelectric materials in which the lead content is suppressed are being developed. As one of such lead-free piezoelectric materials, for example, as in JP-A-2009-130182 and JP-A-2014-107563, a KNN-based piezoelectric body containing potassium sodium niobate (KNN; (K, Na) NbO₃) as a main component has been proposed.

However, in a case where the thickness of KNN is reduced, there is a problem that the insulation property is low and it is difficult to obtain the actual piezoelectric element function. In particular, in a thin film produced by a solution method, since heat treatment for crystallization has to be carried out a plurality of times, alkali volatilization and oxygen vacancy formation, element diffusion, and the like are likely to occur, and the problems described above become more severe than in films manufactured by so-called dry methods such as the sputtering method or the MOCVD method.

In view of this, it has been proposed to improve the insulation property by providing a current blocking layer in addition to the KNN layer between the lower electrode and the upper electrode (refer to JP-A-2009-130182). In addition, it has been proposed to improve the insulation property of the KNN itself by providing at least one layer to which the Mn is added in addition to each KNN layer (refer to JP-A-2014-107563).

However, in JP-A-2009-130182, the insulation property of the KNN itself is not improved, and the voltage applied to the KNN layer is also lowered, thus there is a problem in that it is difficult to obtain excellent piezoelectric characteristics. In addition, in JP-A-2014-107563, since Mn is contained only in a part of the film, it is not possible to obtain sufficient insulation properties. Thus, a piezoelectric element provided with a KNN-based piezoelectric layer with an excellent insulation property is desired.

Here, this problem is not only limited to piezoelectric elements used in piezoelectric actuators mounted in a liquid ejecting head which is represented by an ink jet recording head, but this problem also similarly affects piezoelectric elements used in other piezoelectric element application devices.

### SUMMARY

An advantage of some aspects of the invention is to provide a piezoelectric element using a thin KNN-based piezoelectric body with improved insulation properties, a piezoelectric element application device, and a method for manufacturing a piezoelectric element.

According to an aspect of the invention, there is provided a piezoelectric element including a first electrode, a piezoelectric layer which is a thin film formed on the first electrode and which is formed of a perovskite-type composite oxide including potassium, sodium, and niobium, and a second electrode provided on the piezoelectric layer, in which the composite oxide further includes lithium and manganese, a content of lithium is 3 mol % to 5 mol % in a total number of moles of metal at an A site, a content of manganese is 5 mol % or less in a total number of moles of metal at a B site, and a lithium measured intensity (CPS) maximum value in a film thickness direction of the piezoelectric layer in SIMS measurement is less than 2.65 times a minimum value.

In such an aspect, including Li and Mn at the same time in the KNN-based piezoelectric material remarkably improves the insulation properties of the piezoelectric element and setting the maximum value of the intensity (CPS) to be 2.65 times or less the minimum value when the abundance ratio of Li in the film thickness direction is measured by SIMS sets the leakage current density of the piezoelectric layer to a desired range.

Here, the content of the manganese is preferably 0.3 mol % to 2 mol % in the total number of moles of metal in the B site. According to this, the insulation properties of the piezoelectric element are more reliably improved.

In addition, the first electrode and the second electrode include, for example, at least one type of iridium and platinum, and is able to be formed of a single layer or a plurality of layers.

In addition, it is preferable that the first electrode be provided on the zirconium oxide layer, and the lithium in the piezoelectric layer be segregated on the zirconium oxide layer. Due to this, even if lithium in the piezoelectric layer diffuses to the substrate side, it is possible to suppress reaction with silicon dioxide or the like due to segregation on the zirconium oxide layer.

Furthermore, according to another aspect of the invention, there is provided a piezoelectric element application device including the piezoelectric element.

In such an aspect, it is possible to provide a piezoelectric element application device including a KNN-based piezoelectric layer having excellent an insulation property.

Furthermore, according to still another aspect of the invention, there is provided a method for manufacturing a piezoelectric element provided with a first electrode formed on a substrate, a piezoelectric layer formed of a perovskite-type composite oxide on the first electrode, and a second electrode formed on the piezoelectric layer, the method including forming a thin film of a piezoelectric layer including potassium, sodium, niobium, lithium, and manganese on the first electrode, a content of lithium being 3 mol % to 5 mol % in a total number of moles of metal at an A site, and a content of manganese being 5 mol % or less in a total number of moles of metal at a B site, in which a piezoelectric layer in which a Li measured intensity (CPS) maximum value in a film thickness direction of the piezoelectric layer in SIMS measurement is less than 2.65 times a minimum value is obtained.

In such an aspect, including Li and Mn at the same time in the KNN-based piezoelectric material remarkably improves the insulation properties of the piezoelectric element and setting the maximum value of the intensity (CPS) to 2.65 times or less the minimum value when the abundance ratio of Li in the film thickness direction is measured by SIMS sets the leakage current density of the piezoelectric layer to a desired range.

### BRIEF DESCRIPTION OF THE DRAWINGS

The invention will be described with reference to the accompanying drawings, wherein like numbers reference like elements.

FIG. 1 is a diagram showing a schematic configuration of a recording apparatus.

FIG. 2 is an exploded perspective view of a recording head.

FIG. 3 is a plan view of a recording head.

FIG. 4 is a cross-sectional view of a recording head.

FIG. 5 is a cross-sectional view showing a method for manufacturing a recording head.

FIG. 6 is a cross-sectional view showing a method for manufacturing a recording head.

FIG. 7 is a cross-sectional view showing a method for manufacturing a recording head.

FIG. 8 is a cross-sectional view showing a method for manufacturing a recording head.

FIG. 9 is a cross-sectional view showing a method for manufacturing a recording head.

FIG. 10 is a cross-sectional view showing a method for manufacturing a recording head.

FIG. 11 is a cross-sectional view showing a method for manufacturing a recording head.

FIG. 12 is a diagram showing the results of leakage current density measurement.

FIG. 13 is a diagram showing the results of SIMS measurement of Example 2.

FIG. 14 is a diagram showing the results of SIMS measurement of Comparative Example 6.

### DESCRIPTION OF EXEMPLARY EMBODIMENTS

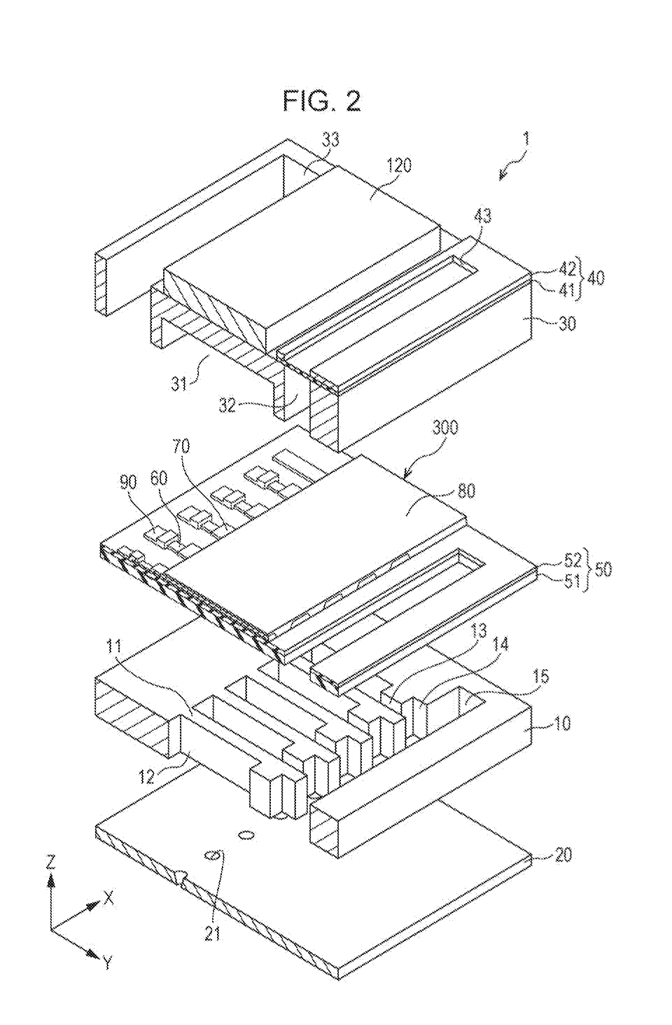

A description will be given below of embodiments of the invention with reference to the drawings. However, the following description illustrates one aspect of the invention and can be changed in an optional manner within the scope of the invention. The same reference numerals are applied in each of the diagrams to illustrate the same members and explanation thereof is omitted as appropriate. In addition, in FIG. 2 to FIG. 11, X, Y, and Z represent three spatial axes which are perpendicular to each other. In the present specification, directions along these axes will be described as the X direction, Y direction, and Z direction. The Z direction represents the thickness direction or stacking direction of the plate, layer, and film. The X direction and the Y direction represent in-plane directions of the plate, layer, and film.

### Embodiment 1

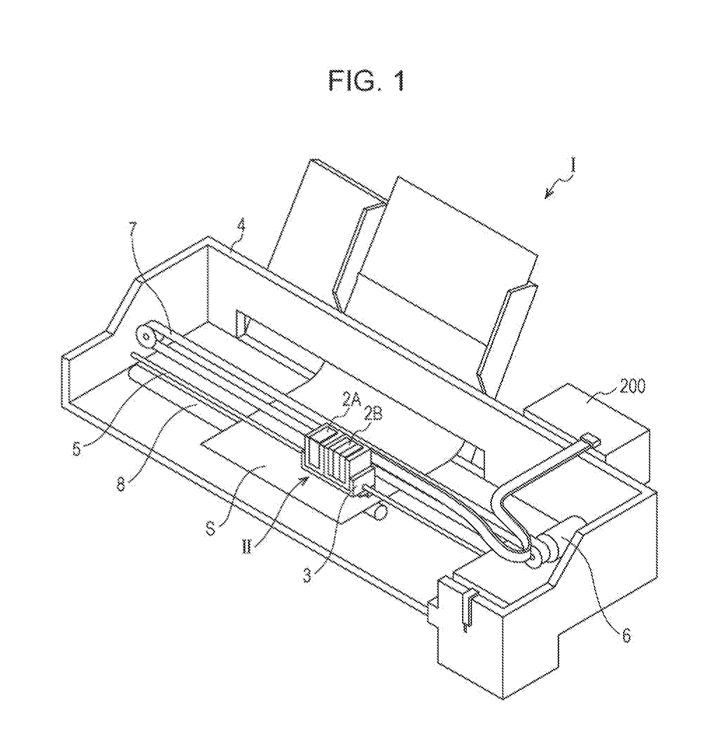

FIG. 1 is an ink jet recording apparatus which is an example of a liquid ejecting apparatus on which a liquid ejecting head according to an embodiment of the invention is mounted. As shown in the drawing, in an ink jet recording apparatus I, an ink jet recording head unit (head unit) II having a plurality of ink jet recording heads is detachably provided with cartridges 2A and 2B forming ink supply means. A carriage 3 on which the head unit II is mounted is provided so as to be movable in the axial direction on a carriage shaft 5 attached to an apparatus main body 4 and, for example, discharges a black ink composition and a color ink composition, respectively.

Here, the carriage 3 on which the head unit II is mounted is moved along the carriage shaft 5 by transmitting the driving force of a driving motor 6 to the carriage 3 via a plurality of gears (not shown) and a timing belt 7. Meanwhile, a transport roller 8 is provided as a transport means in the apparatus main body 4, and a recording sheet S which is a recording medium such as paper is transported by the transport roller 8. The transport means which transports the recording sheet S is not limited to being the transport roller 8 and may be a belt, a drum, or the like.

The ink jet recording apparatus I makes low cost manufacturing possible since the ink jet recording head (simply referred to below as “recording head”) according to the present embodiment is provided as an ink jet recording head. In addition, using a piezoelectric element to be described later in detail is also expected to improve the displacement characteristics of the piezoelectric element forming the piezoelectric actuator, making it possible to improve the ejection characteristics.

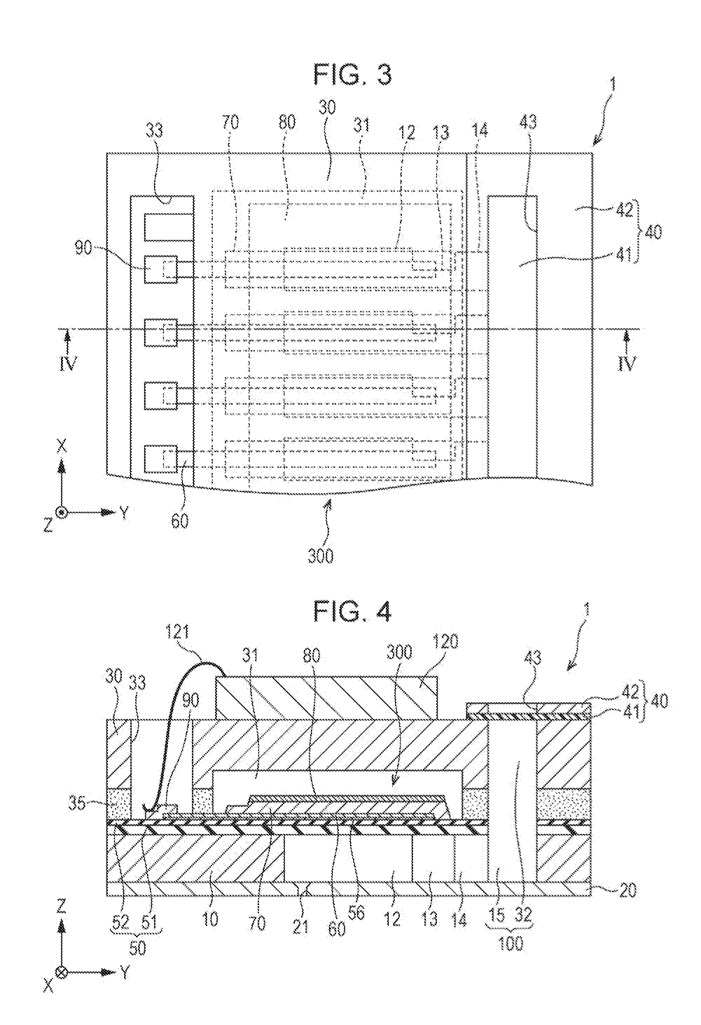

Description will be given of an example of a recording head 1 mounted on the ink jet recording apparatus I described above with reference to FIG. 2 to FIG. 4. FIG. 2 is an exploded perspective view of a recording head which is an example of a liquid ejecting head according to the present embodiment. FIG. 3 is a plan view of the piezoelectric element side of a flow path forming substrate, and FIG. 4 is a cross-sectional view taken along line IV-IV of FIG. 3.

A flow path forming substrate 10 (referred to below as the substrate 10) is formed of, for example, a silicon single crystal substrate, and forms a pressure-generating chamber 12. A plurality of nozzle openings 21 for ejecting ink of the same color are aligned in the X direction in the pressure-generating chamber 12 partitioned by a plurality of partition walls 11.

In the substrate 10, an ink supply path 13 and a communication path 14 are formed on one end side of the pressure-generating chamber 12 in the Y direction. The ink supply path 13 is formed such that the opening area is reduced by narrowing one side of the pressure-generating chamber 12 in the X direction. In addition, the communication path 14 has substantially the same width as the pressure-generating chamber 12 in the X direction. A communication unit 15 is formed on the outside (on the +Y direction side) of the communication path 14. The communication unit 15 forms a part of a manifold 100. The manifold 100 forms a common ink chamber for each of the pressure-generating chambers 12. In this manner, a liquid flow path formed of the pressure-generating chambers 12, the ink supply path 13, the communication path 14, and the communication unit 15 is formed on the substrate 10.

A nozzle plate 20 made of, for example, SUS is bonded on one surface (surface on the −Z direction side) of the substrate 10. The nozzle openings 21 are provided aligned in the X direction on the nozzle plate 20. The nozzle openings 21 communicate with each pressure-generating chamber 12. The nozzle plate 20 can be bonded to the substrate 10 by an adhesive, a heat welding film, or the like.

On the other surface (the surface on the +Z direction side) of the substrate 10, a vibrating plate 50 is formed. The vibrating plate 50 is, for example, formed of an elastic film 51 formed on the substrate 10 and an insulating film 52 formed on the elastic film 51. The elastic film 51 is, for example, formed of silicon dioxide (SiO₂) and the insulating film 52 is, for example, formed of zirconium oxide (ZrO₂). The elastic film 51 need not be a member separate from the substrate 10. A part of the substrate 10 is processed to be thin and may be used as an elastic film.

A piezoelectric element 300 including a first electrode 60, a piezoelectric layer 70, and a second electrode 80 is formed on the insulating film 52 with an adhesion layer 56 interposed therebetween. The adhesion layer 56 is for improving the adhesion between the first electrode 60 and the base and it is possible to use, for example, titanium oxide (TiOₓ), titanium (Ti), silicon nitride (SiN), or the like as the adhesion layer 56. In addition, in a case where the adhesion layer 56 formed of titanium oxide (TiOₓ), titanium (Ti), silicon nitride (SiN), or the like is provided, the adhesion layer 56 has a function, in the same manner as the insulating film 52, as a stopper for preventing potassium and sodium as constituent elements of the piezoelectric layer 70 from passing through the first electrode 60 and reaching the substrate 10 when the piezoelectric layer 70 described below is formed. Here, it is possible to omit the adhesion layer 56.

In the present embodiment, the vibrating plate 50 and the first electrode 60 are displaced by the displacement of the piezoelectric layer 70 having electromechanical conversion characteristics. That is, in the present embodiment, the vibrating plate 50 and the first electrode 60 substantially function as a vibrating plate. The elastic film 51 and the insulating film 52 may be omitted so that only the first electrode 60 functions as a vibrating plate. In a case where the first electrode 60 is provided directly on the substrate 10, it is preferable to protect the first electrode 60 with an insulating protective film or the like such that the ink does not contact the first electrode 60.

The first electrode 60 is divided for each pressure-generating chamber 12, that is, the first electrode 60 is formed as an individual electrode which is independent for each pressure-generating chamber 12. The first electrode 60 has a width narrower than the width of the pressure-generating chamber 12 in the X direction. In addition, the first electrode 60 is formed with a wider width in the Y direction than the pressure-generating chamber 12. That is, in the Y direction, both end portions of the first electrode 60 are formed to the outside of a region facing the pressure-generating chamber 12. In the Y direction, a lead electrode 90 is connected to one end side (the opposite side to the communication path 14) of the first electrode 60.

The piezoelectric layer 70 is provided between the first electrode 60 and the second electrode 80. The piezoelectric layer 70 is formed with a wider width in the X direction than the first electrode 60. In addition, the piezoelectric layer 70 is formed with a width in the Y direction wider than the length of the pressure-generating chamber 12 in the Y direction. In the Y direction, the end portion (the end portion in the +Y direction) of the piezoelectric layer 70 on the ink supply path 13 side is formed to the outside of the end portion of the first electrode 60. That is, the other end portion (the end portion on the +Y direction side) of the first electrode 60 is covered with the piezoelectric layer 70. On the other hand, one end portion (the end portion on the −Y direction side) of the piezoelectric layer 70 is inside the one end portion (the end portion on the −Y direction side) of the first electrode 60. That is, one end portion (the end portion on the −Y direction side) of the first electrode 60 is not covered with the piezoelectric layer 70.

The second electrode 80 is provided continuously over the piezoelectric layer 70, the first electrode 60, and the vibrating plate 50 in the X direction. That is, the second electrode 80 is formed as a common electrode common to the plurality of piezoelectric layers 70. Here, instead of the second electrode 80, the first electrode 60 may be used as a common electrode.

A protective substrate 30 is bonded by an adhesive 35 on the substrate 10 on which the piezoelectric elements 300 are formed. The protective substrate 30 has a manifold unit 32. At least a portion of the manifold 100 is formed of the manifold unit 32. The manifold unit 32 according to the present embodiment extends through the protective substrate 30 in the thickness direction (Z direction) and is formed across the width direction (X direction) of the pressure-generating chambers 12. Then, as described above, the manifold unit 32 communicates with the communication unit 15 of the substrate 10. According to this configuration, the manifold 100 which forms a common ink chamber for each of the pressure-generating chambers 12 is formed.

In the protective substrate 30, a piezoelectric element holding unit 31 is formed in a region including the piezoelectric element 300. The piezoelectric element holding unit 31 has a space large enough not to hinder the movement of the piezoelectric element 300. This space may or may not be sealed. In the protective substrate 30, a through hole 33 which passes through the protective substrate 30 in the thickness direction (Z direction) is provided. In the through hole 33, the end portions of the lead electrodes 90 are exposed.

On the protective substrate 30, a driving circuit 120 which functions as a signal processing unit is fixed. The driving circuit 120 can use, for example, a circuit board or a semiconductor integrated circuit (IC). The driving circuit 120 and the lead electrode 90 are electrically connected via a connection wiring 121. It is possible for the driving circuit 120 to be electrically connected to a printer controller 200. The driving circuit 120 functions as the control means according to the present embodiment.

A compliance substrate 40 formed of a sealing film and a fixing plate 42 is bonded onto the protective substrate 30. The region of the fixing plate 42 facing the manifold 100 is an opening 43 completely removed in the third direction Z which is the thickness direction. One surface (the surface on the +Z direction side) of the manifold 100 is sealed with only the flexible sealing film 41.

Next, detailed description will be given of the piezoelectric element 300. The piezoelectric element 300 includes the first electrode 60, the second electrode 80, and the piezoelectric layer 70 provided between the first electrode 60 and the second electrode 80. The thickness of the first electrode 60 is approximately 50 nm. The piezoelectric layer 70 is a so-called thin-film piezoelectric body having a thickness of 50 nm or more and 2000 nm or less. The thickness of the second electrode 80 is approximately 50 nm. The thickness of each of the elements listed here is merely an example and is able to be changed within a range not changing the gist of the invention.

The material of the first electrode 60 and the second electrode 80 is preferably a noble metal such as platinum (Pt) or iridium (Ir). The material of the first electrode 60 and the material of the second electrode 80 may be any material having conductivity. The material of the first electrode 60 and the material of the second electrode may be the same or different. In addition, the electrodes may be a single layer or a laminate of a plurality of layers.

The piezoelectric layer 70 is a thin film formed by various manufacturing methods and is a perovskite-type composite oxide represented by General Formula ABO₃ including potassium (K), sodium (Na), and niobium (Nb). That is, the piezoelectric layer 70 includes a piezoelectric material formed of a KNN-based composite oxide represented by Formula (1). The piezoelectric layer 70 is preferably manufactured using a chemical solution method (wet method) such as a Metal-Organic Decomposition (MOD) method or a sol-gel method; however, manufacturing is possible using a gas phase method, a liquid phase method, or a solid phase method such as a laser ablation method, a sputtering method, a pulse laser deposition method (PLD method), a CVD (Chemical Vapor Deposition) method, or an aerosol deposition method.

{(K_{X}, Na_{1-X})_{1-Y}, Li_{Y}} (Nb_{1-P}, Mn_{P})O₃ (1)

### (0.1≤X≤0.9, 0.03≤Y≤0.05, P≤0.05)

The composite oxide represented by Formula (1) is a so-called KNN-based composite oxide. Since the KNN-based composite oxide is a lead-free piezoelectric material in which the content of lead (Pb) and the like is suppressed, the KNN-based composite oxide is excellent in biocompatibility and the environmental impact is also small. Moreover, since the KNN-based composite oxide is excellent in piezoelectric characteristics among the lead-free piezoelectric materials, it is advantageous for improving various characteristics. In addition, since the KNN-based composite oxide has a relatively high Curie temperature and is hardly depolarized due to temperature increases in comparison with other lead-free piezoelectric materials (for example, BNT-BKT-BT;[(Bi,Na)TiO₃]—[(Bi,K)TiO₃]—[BaTiO₃]), use at high temperatures is possible.

In Formula (1), the content of K is preferably 30 mol % or more and 70 mol % or less with respect to the total amount of the metal elements forming the A site (in other words, the content of Na is 30 mol % or more and 70 mol % or less with respect to the total amount of the metal element forming the A site). That is, in Formula (1), it is preferable that 0.3≤x≤0.7. According to this, a composite oxide having a composition with advantageous piezoelectric characteristics is obtained. In addition, the content of K is more preferably 35 mol % or more and 55 mol % or less with respect to the total amount of the metal elements forming the A site (in other words, the content of Na is 45 mol % or more and 65 mol % or less with respect to the total amount of the metal elements forming the A site). That is, in Formula (1), it is more preferable that 0.35≤X≤0.55. According to this, a composite oxide with more advantageous piezoelectric characteristic is obtained.

The piezoelectric material forming the piezoelectric layer 70 further contains lithium and manganese. In this manner, Li and Mn being simultaneously contained in the KNN-based piezoelectric material makes it possible to remarkably improve the insulation property of the piezoelectric layer 70.

The content of lithium is 3 mol % to 5 mol % in the total number of moles of metal in the A site, that is, in the above formula, 0.03≤Y≤0.05. When the amount of lithium is less than 3 mol %, the effect of improving the insulation property becomes insignificant. In addition, when the amount of lithium increases, there is a high possibility that segregation will occur in the thickness direction of the piezoelectric layer 70, and the segregation problem as described later tends to occur.

In addition, the content of manganese is 5 mol % or less, preferably 0.3 mol % to 2 mol %, in the total number of moles of metal in the B site, that is, in the above formula, P≤0.05, and preferably 0.003≤P≤0.02. When the content of Mn is small, the effect of improving the insulation property becomes insignificant, while when the content of manganese is excessively large, the crystallinity of the piezoelectric layer 70 is decreased and there is an increased tendency for the piezoelectric characteristics to decrease.

In the invention, the insulation properties are remarkably improved by simultaneously containing Li and Mn in a predetermined amount range in the KNN-based piezoelectric material.

The bulk KNN-based piezoelectric material has an orthorhombic crystal structure at room temperature and a tetragonal crystal structure at approximately 200° C. and it is known that adding Li shifts the phase boundary of this crystal structure to the room temperature side to improve the piezoelectric characteristics. However, the thin film piezoelectric material as in the invention generally has pseudocubic crystals and has a different crystal structure from the bulk KNN-based piezoelectric material, such that it is not possible to apply the findings to the bulk KNN-based piezoelectric material.

In the invention, although Li and Mn are simultaneously contained in a predetermined amount range in the KNN-based piezoelectric material, it is important to prevent the abundance ratio of Li from deviating in the film thickness direction of the piezoelectric layer 70, and, in particular, It is necessary to prevent segregation on the side of the first electrode 60 where the piezoelectric layer 70 is provided. As will be described in detail later, when Li segregates on the side of the first electrode 60, improvement in the insulation property is not observed.

Here, segregation means that there is a region where the abundance ratio of Li is unbalanced and it was found that, according to a test example described later, when the abundance ratio of Li in the film thickness direction in the piezoelectric layer is measured by SIMS, the maximum value of the intensity (CPS) being less than 2.65 times the minimum value sets the leakage current density of the piezoelectric layer 70 to a desired range.

As is clear from specific examples to be described later, the segregation state of lithium largely varies depending on the manufacturing conditions of the piezoelectric layer. In particular, depending on how the piezoelectric material is crystallized, the diffusion state of lithium changes and the state of segregation changes.

For example, it is understood that lithium is likely to be segregated on the first electrode 60 side of the piezoelectric layer 70 because, when the temperature is raised slowly during heating for crystallization, instead of the constituent elements being crystallized almost at the same time, the elements that are easily attracted to the electrode are gathered and crystallized in order starting with the one with the lowest crystallization temperature.

The piezoelectric material forming the piezoelectric layer 70 may be any KNN-based composite oxide, and is not limited to the composition represented by Formula (1). For example, metal elements (additives) other than Li and Mn may be included in the A site and B site of sodium potassium niobate. Examples of such additives are barium (Ba), calcium (Ca), strontium (Sr), zirconium (Zr), titanium (Ti), bismuth (Bi), tantalum (Ta), antimony (Sb), iron (Fe), cobalt (Co), silver (Ag), magnesium (Mg), zinc (Zn), and copper (Cu).

One or more additives of this type may be included. Generally, the amount of the additive is 20% or less, preferably 15% or less, more preferably 10% or less with respect to the total amount of the main element. Using additives makes it easy to improve various characteristics so as to diversify the structure and functions, but it is preferable to have more than 80% of KNN from the viewpoint of exhibiting the characteristics derived from KNN. Here, also in the case of a composite oxide including these other elements, it is preferable to have an ABO₃ type perovskite structure.

The alkali metal of the A site may be added in excess to the stoichiometric composition. Also, the alkali metal of the A site may be lacking with respect to the stoichiometric composition. Accordingly, it is possible to represent the composite oxide of the present embodiment by Formula (2). In Formula (2), A represents the amounts of K and Na which may be added excessively or the amounts of K and Na which may be lacking. In a case where the amounts of K and Na are excessive, 1.0<A. In a case where the amounts of K and Na are lacking, A<1.0. For example, A=1.1 represents that 110 mol % of K and Na are included when the amounts of K and Na in the stoichiometric composition are 100 mol %. A=0.9 represents that 90 mol % of K and Na are included when the amounts of K and Na in the stoichiometric composition are 100 mol %. Here, in a case where the alkali metal of the A site is neither excessive nor lacking with respect to the stoichiometric composition, A=1. From the viewpoint of improvement in the characteristics, 0.85≤A≤1.15, preferably 0.90≤A≤1.10, and more preferably 0.95≤A≤1.08.

{(K_{AX}, Na_{A(1-X)})_{1-Y}Li_{Y}} (Nb_{1-P}, Mn_{P})O₃ (2)

(0.1≤X≤0.9, preferably 0.3≤X≤0.7, and more preferably 0.35≤X≤0.55)

Piezoelectric materials also include materials having a composition lacking some of the elements, materials having a composition in which some of the elements are excessive, and materials having a composition in which some of the elements are substituted with other elements. As long as the fundamental characteristics of the piezoelectric layer 70 are not changed, materials which deviate from the stoichiometric composition due to such lack/excess or materials in which a part of the element is substituted with another element are also included in the piezoelectric material according to the present embodiment.

In addition, in the present specification, the “composite oxide having an ABO₃ type perovskite structure including K, Na, and Nb” is not limited only to a composite oxide having an ABO₃ type perovskite structure including K, Na, and Nb. That is, in the present specification, “a composite oxide having an ABO₃ type perovskite structure including K, Na, and Nb” includes piezoelectric materials represented by mixed crystals including a composite oxide having an ABO₃ type perovskite structure including K, Na, and Nb (for example, a KNN-based composite oxide exemplified above) and another composite oxide having an ABO₃ type perovskite structure.

The other composite oxide is not limited within the scope of the invention, but is preferably a lead-free piezoelectric material not containing lead (Pb). In addition, it is more preferable that the other composite oxide be a lead-free piezoelectric material not containing lead (Pb) and bismuth (Bi). Accordingly, the piezoelectric element 300 is excellent in biocompatibility and the environmental impact is also small.

In the present embodiment, the piezoelectric layer formed of a composite oxide as described above is preferentially oriented with respect to a predetermined crystal plane. For example, the piezoelectric layer 70 formed of the KNN-based composite oxide tends to be naturally oriented on the (100) plane. In addition, the piezoelectric layer 70 may be preferentially oriented in the (110) plane or the (111) plane depending on a predetermined orientation control layer provided as necessary. The piezoelectric layer 70 preferentially oriented to a predetermined crystal plane easily improves various characteristics as compared with a randomly oriented piezoelectric layer. In this specification, preferential orientation means that crystals of 50% or more, preferably 80% or more, are oriented in a predetermined crystal plane. For example, “preferentially oriented in the (100) plane” includes a case where all the crystals of the piezoelectric layer 70 are oriented in the (100) plane and a case where half or more of the crystals (50% or more, preferably 80% or more) are oriented in the (100) plane.

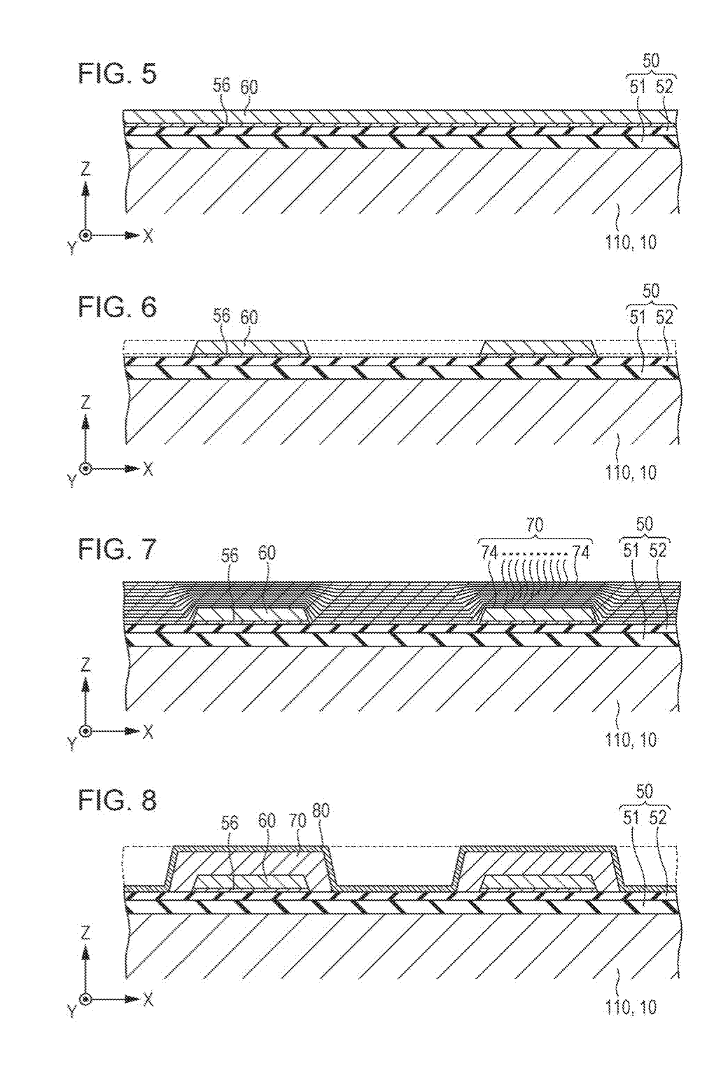

Next, with reference to FIG. 5 to FIG. 11, description will be given of an example of a method for manufacturing the piezoelectric element 300 together with a method for manufacturing the ink jet recording head 1. First, a wafer 110 is prepared as a silicon substrate. Next, by thermal oxidation of the wafer 110, the elastic film 51 formed of silicon dioxide is formed on the surface thereof. Furthermore, a zirconium film is formed on the elastic film by a sputtering method, and the insulating film 52 is formed by thermal oxidation of the zirconium film. In this manner, the vibrating plate 50 formed of the elastic film 51 and the insulating film 52 is obtained. Next, the adhesion layer 56 formed of titanium oxide is formed on the insulating film 52 by a sputtering method, thermal oxidation of a titanium film, or the like. Then, as shown in FIG. 5, the first electrode 60 is formed on the adhesion layer 56 by a sputtering method, an evaporation method, or the like.

Next, as shown in FIG. 6, a resist (not shown) having a predetermined shape is formed on the first electrode 60 as a mask, and the adhesion layer 56 and the first electrode 60 are simultaneously patterned. Next, as shown in FIG. 7, a plurality of layers of piezoelectric films 74 are formed in layers so as to overlap the adhesion layer 56, the first electrode 60, and the vibrating plate 50. The piezoelectric layer 70 is formed by the plurality of layers of the piezoelectric films 74. In addition, it is possible to form the piezoelectric layer 70 by a solution method (chemical solution method) such as an MOD method or a sol-gel method. Forming the piezoelectric layer 70 by the solution method as described above makes it possible to improve the productivity of the piezoelectric layer 70. The piezoelectric layer 70 formed by the solution method as described above is formed by repeating a series of steps from the step of coating the precursor solution (coating step) to the step of firing the precursor film (firing step) a plurality of times.

In the layer or film formed by the wet method, traces of coating or firing remain and such traces form an “interface” which is able to be confirmed by observation of the cross-section or analysis of the concentration distribution of elements in the layer (or in the film). “Interface” strictly means a boundary between layers or between films, but in this case has the meaning of near the boundary of a layer or a film. In a case where a cross-section of a layer or film formed by the solution method is observed with an electron microscope or the like, such an interface is confirmed in the vicinity of the boundary with the adjacent layer and the film as a portion where the color is thinner than the other parts or a portion where the color is thicker than the other parts. In addition, in a case of analyzing the concentration distribution of elements, such an interface is confirmed as a portion where the concentration of the element is higher than the other parts, or a portion where the concentration of the element is lower than the other parts in the vicinity of the boundary with the adjacent layer or film. Since the piezoelectric layer is formed by repeatedly applying a coating step and a firing step a plurality of times (formed by a plurality of piezoelectric films 74), there are a plurality of interfaces corresponding to each piezoelectric film 74.

The specific procedure in the case of forming the piezoelectric layer 70 by the solution method is as follows, for example. First, a precursor solution containing a predetermined metal complex is prepared. The precursor solution is obtained by dissolving or dispersing a metal complex, which is capable of forming a composite oxide including K, Na, Nb, Li and Mn by firing, in an organic solvent. At this time, a metal complex including other additives may be further mixed therein.

Examples of metal complexes which include K include potassium 2-ethyl hexane acid, potassium acetate, and the like. Examples of metal complexes which include Na include sodium 2-ethyl hexane acid, sodium acetate, and the like. Examples of metal complexes which include Nb include niobium 2-ethylhexanoate, pentaethoxy niobium, and the like. Examples of metal complexes which include Li include lithium 2-ethylhexanoate, lithium acetate, and the like. Examples of metal complexes which include Mn include manganese 2-ethylhexanoate, and the like. At this time, two or more types of metal complexes may be used in combination. For example, potassium 2-ethylhexanoate and potassium acetate may be used in combination as a metal complex including K. Examples of solvents include 2-n butoxyethanol or n-octane, a mixed solvent thereof, or the like. The precursor solution may include stabilizing additives for metal complexes including K, Na, Nb, Li, and Mn. Examples of such additives include 2-ethylhexanoic acid and the like.

Then, the precursor solution described above is applied onto the wafer 110 on which the vibrating plate 50, the adhesion layer 56, and the first electrode 60 are formed to form a precursor film (coating step). Next, the precursor film is heated to a predetermined temperature, for example, approximately 130° C. to 250° C. and dried for a certain period of time (drying step). Next, the dried precursor film is heated to a predetermined temperature, for example, 300° C. to 450° C., and kept at this temperature for a certain period of time to carry out degreasing (degreasing step). Finally, the degreased precursor film is heated to a higher temperature, for example, approximately 500° C. to 700° C., and is kept at this temperature for a certain period of time to carry out crystallization, thereby completing the piezoelectric film 74 (firing step). In addition, it is preferable that the temperature rising rate in the drying step be 20° C. to 350° C./sec. Firing the piezoelectric film 74 with such a temperature rising rate using the solution method makes it possible to realize the piezoelectric layer 70 which is not pseudocubic crystal. The term “temperature rising rate” as used here defines the time rate of change of the temperature from 350° C. until the target firing temperature is reached.

Examples of the heating apparatus used in the drying step, the degreasing step, and the firing step include a Rapid Thermal Annealing (RTA) apparatus which heats by irradiation with an infrared lamp, a hot plate, or the like. The piezoelectric layer 70 formed of the plurality of layers of the piezoelectric film 74 is formed by repeating the above steps a plurality of times. Here, in the series of steps from the coating step to the firing step, the firing step may be carried out after repeating the coating step to the degreasing step a plurality of times.

In addition, before and after forming the second electrode 80 on the piezoelectric layer 70, a reheating treatment (post-annealing) may be performed in a temperature range of 600° C. to 800° C. according to necessity. In this manner, performing the post-annealing makes it possible to form a favorable interface between the piezoelectric layer 70 and the first electrode 60 or the second electrode 80 and to improve the crystallinity of the piezoelectric layer 70.

In the present embodiment, the piezoelectric material includes an alkali metal (K or Na). The alkali metal easily diffuses into the first electrode 60 and into the adhesion layer 56 in the firing step. If the alkali metal passes through the first electrode 60 and the adhesion layer 56 and reaches the wafer 110, the alkali metal reacts with the wafer 110. However, in the present embodiment, the insulating film 52 formed of the above-mentioned zirconium oxide functions as a stopper of K, Na, or Li. Accordingly, it is possible to suppress the alkali metal from reaching the wafer 110, which is a silicon substrate.

Thereafter, the piezoelectric layer 70 formed of the plurality of piezoelectric films 74 is patterned to have a shape as shown in FIG. 8. It is possible to perform the patterning by dry etching such as reactive ion etching or ion milling or wet etching using an etching solution. Thereafter, the second electrode 80 is formed on the piezoelectric layer 70. It is possible to form the second electrode 80 by a method similar to that of the first electrode 60. Through the above steps, the piezoelectric element 300 provided with the first electrode 60, the piezoelectric layer 70, and the second electrode 80 is completed. In other words, a portion where the first electrode 60, the piezoelectric layer, and the second electrode 80 overlap is the piezoelectric element 300.

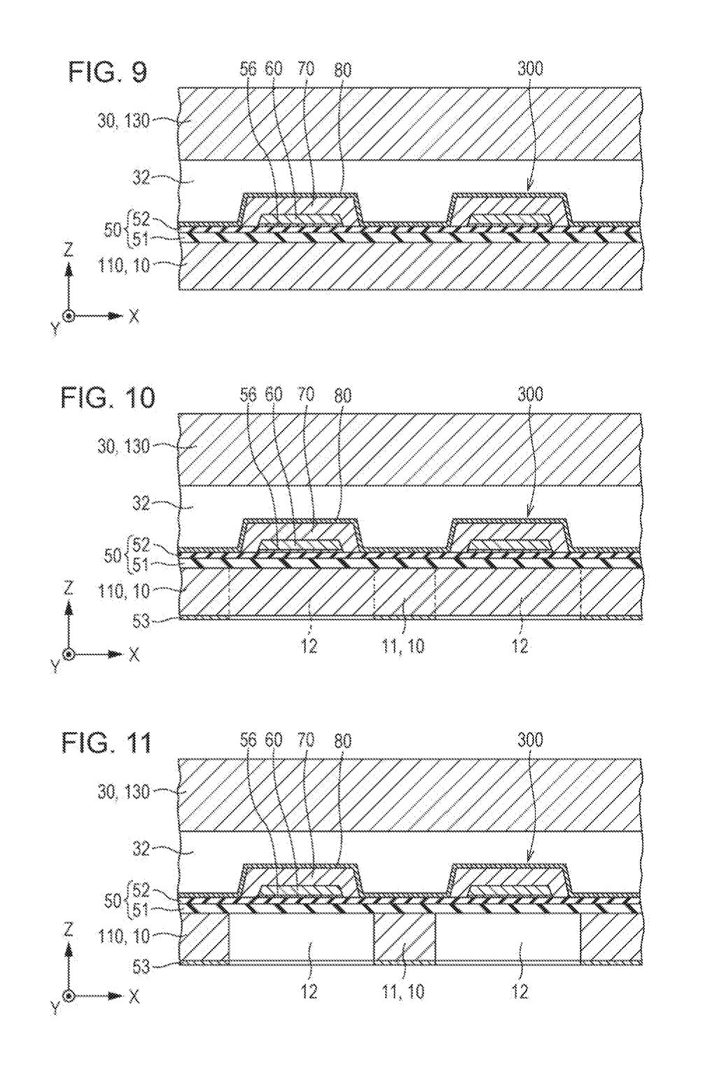

Next, as shown in FIG. 9, a protective substrate wafer 130 is bonded with the surface of the wafer 110 on the piezoelectric element 300 side via the adhesive 35 (refer to FIG. 4). After that, the surface of the protective substrate wafer 130 is thinned by abrasion. In addition, the manifold unit 32 and the through hole 33 (refer to FIG. 4) are formed in the protective substrate wafer 130. Next, as shown in FIG. 10, a mask film 53 is formed on the surface of the wafer 110 on the opposite side to the piezoelectric element 300 and patterned into a predetermined shape. Then, as shown in FIG. 11, anisotropic etching (wet etching) using an alkali solution such as KOH is carried out on the wafer 110 via the mask film 53. Due to this, in addition to the pressure-generating chambers 12 corresponding to the individual piezoelectric elements 300, the ink supply path 13, the communication path 14, and the communication unit 15 (refer to FIG. 4) are formed.

Next, unnecessary portions of the outer peripheral edge of the wafer 110 and the protective substrate wafer 130 are cut and removed by dicing or the like. Furthermore, the nozzle plate 20 is bonded to the surface of the wafer 110 opposite to the piezoelectric element 300 (refer to FIG. 4). In addition, the compliance substrate 40 is bonded to the protective substrate wafer 130 (refer to FIG. 4). Through the steps so far, an aggregate of chips of the ink jet recording head 1 is completed. The ink jet recording heads are obtained by dividing this aggregate into individual chips.

### EXAMPLES

A description will be given below of Examples of the invention.

### Example 1

By thermal oxidation of the surface of the silicon substrate which is the substrate 10, the elastic film 51 formed of silicon dioxide was formed on the silicon substrate. Next, by forming a zirconium film by a sputtering method on the elastic film 51 and carrying out thermal oxidation on the zirconium film, the insulating film 52 formed of zirconium oxide was formed. Next, titanium was deposited on the insulating film 52 by a sputtering method and thermally oxidized to form the adhesion layer 56 formed of titanium oxide. Platinum was deposited on the adhesion layer 56 by a sputtering method and then patterned into a predetermined shape to form the first electrode 60 having a thickness of 50 nm.

Next, the piezoelectric layer 70 was formed by the following procedure. First, a solution formed of potassium 2-ethylhexanoate, sodium 2-ethylhexanoate, niobium 2-ethylhexanoate, lithium 2-ethylhexanoate, and manganese 2-ethylhexanoate was prepared and used to prepare the precursor solution having the following composition.

(K_{0.388} Na_{0.582} Li_{0.03}) (Nb_{0.995} Mn_{0.005}) O₃

The precursor solution was coated on the substrate by a spin coating method (coating step). Thereafter, the silicon substrate was placed on a hot plate and dried at 180° C. for 4 minutes (drying step). Next, degreasing was performed at 380° C. for 4 minutes (degreasing step). Then, a heat treatment was performed at 500° C. for 3 minutes using a Rapid Thermal Annealing (RTA) apparatus (first firing step). After repeating this coating step to the first firing step seven times, an additional heat treatment was further carried out at 700° C. using an electric furnace (second firing step), whereby the piezoelectric layer 70 formed of sodium potassium niobate (KNN) was produced.

The second electrode 80 was formed by depositing platinum on the piezoelectric layer 70 by a sputtering method.

Thereafter, in order to improve adhesion between the platinum and the piezoelectric layer, a silicon substrate was placed on the hot plate and reheated (post anneal) at 650° C. for 3 minutes to form the piezoelectric element of the example.

### Example 2

The procedure of Example 1 was repeated except that the piezoelectric layer was made to have the following composition.

(K_{0.38} Na_{0.57} Li_{0.05}) (Nb_{0.995} Mn_{0.005}) O₃

### Example 3

The procedure of Example 1 was repeated except that the piezoelectric layer was made to have the following composition.

(K_{0.36} Na_{0.54} Li_{0.10}) (Nb_{0.995} Mn_{0.005}) O₃

### Example 4

The procedure of Example 1 was repeated except that the piezoelectric layer was made to have the following composition.

(K_{0.388} Na_{0.582} Li_{0.03}) (Nb_{0.997} Mn_{0.003}) O₃

### Example 5

The procedure of Example 1 was repeated except that the piezoelectric layer was made to have the following composition.

(K_{0.388} Na_{0.582} Li_{0.03}) (Nb_{0.98} Mn_{0.02}) O₃

### Comparative Example 1

The procedure of Example 1 was repeated except that the piezoelectric layer was made to have the following composition.

(K_{0.4} Na_{0.60}) NbO₃

### Comparative Example 2

The procedure of Example 1 was repeated except that the piezoelectric layer was made to have the following composition.

(K_{0.4} Na_{0.60}) (Nb_{0.995} Mn_{0.005}) O₃

### Comparative Example 3

The procedure of Example 1 was repeated except that the piezoelectric layer was made to have the following composition.

(K_{0.38} Na_{0.57} Li_{0.05}) NbO₃

### Comparative Example 4

The procedure of Example 1 was repeated except that the piezoelectric layer was made to have the following composition.

(K_{0.394} Na_{0.591} Li_{0.015}) (Nb_{0.996} Mn_{0.004}) O₃

### Comparative Example 5

The procedure of Example 1 was repeated except that the piezoelectric layer was made to have the following composition.

(K_{0.394} Na_{0.591} li_{0.015}) (Nb_{0.896} Mn_{0.004} Sr_{0.03} Ba_{0.001} Zr_{0.03} Ta_{0.04}) O₃

### Comparative Example 6

The same procedure as in Example 1 was carried out except that the piezoelectric layer was made to have the same composition as in Example 2 and the heating temperature for the heat treatment by RTA was 10° C./sec.

### Measurement of Leakage Current Density

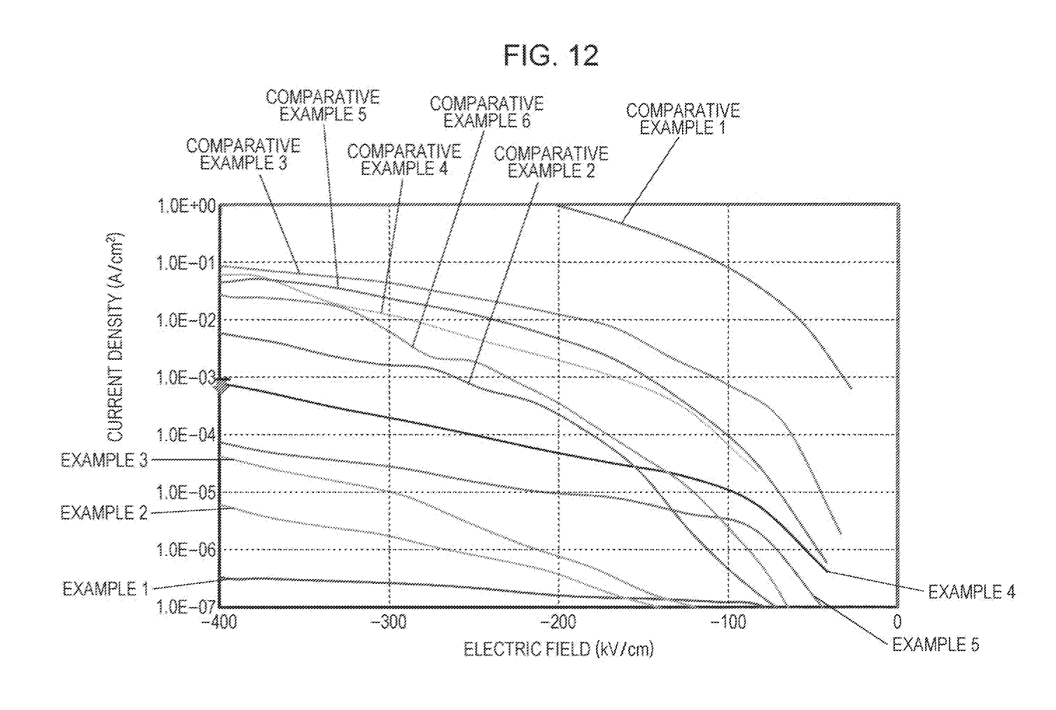

The leakage current densities of the respective Examples and Comparative Examples were measured using “4140 B” manufactured by Hewlett-Packard Company, under the conditions that the holding time for measurement was 2 seconds and a voltage of ±50 V was applied in the atmosphere. FIG. 12 shows the result of converting the applied voltage into an electric field.

### SIMS Measurement

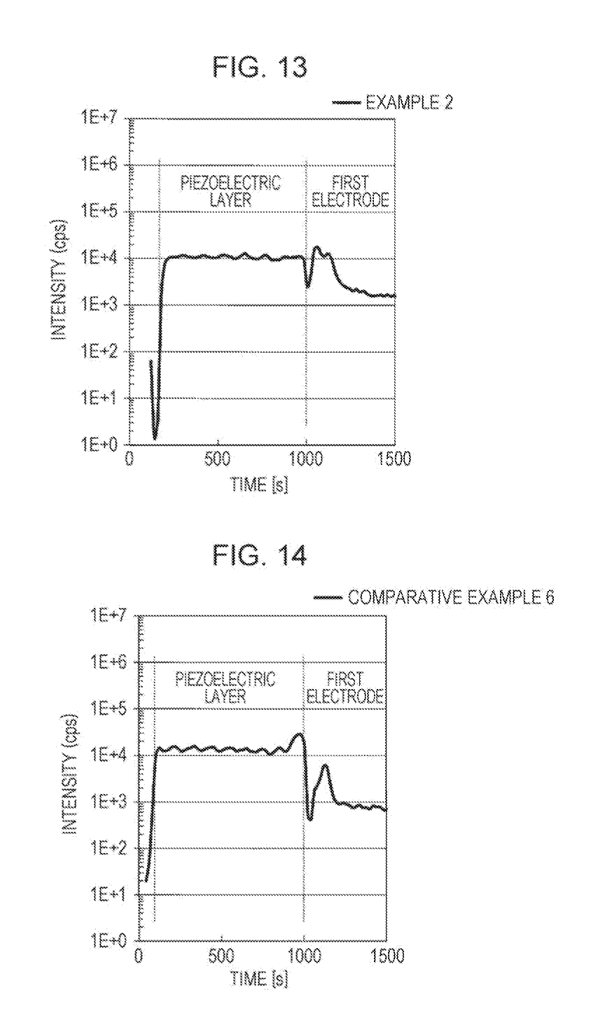

Secondary ion mass spectrometry (SIMS) was performed on the piezoelectric layer of Example 2 and the piezoelectric layer of Comparative Example 6 in the thickness direction of the piezoelectric layer to examine the state of the Li. As a secondary ion mass spectrometer (SIMS), “ADEPT-1010” manufactured by ULVAC-PHI Inc. was used. The results are shown in FIG. 13 and FIG. 14. The vertical axis in the figure is the detection intensity normalized by ⁹⁰Zr+¹⁶O, the horizontal axis is the sputtering time, and the sputtering time corresponds to the depth direction.

### Test Results

From FIG. 12, it is understood that, in Examples 1 to 5, the leakage current density was 1×10⁻³ A/cm² or less at an applied electric field of −400 kV/cm², whereas in Comparative Examples 1 to 6, a leakage current of 1×10⁻³ A/cm² or more was generated.

Comparative Examples 1 to 3 did not include Li and Mn at the same time and it was confirmed that there was no effect of suppressing the leakage current.

In addition, in Comparative Examples 4 and 5, the same composition as that of the example of JP-A-2014-107563 using the gas phase method was formed by the solution method, but the effect of suppressing the leakage current was not obtained.

In addition, in Comparative Example 6 containing Li and Mn at the same time and having the same composition as in Example 2, the leakage current density was high. This is due to the segregation of lithium present in the vicinity of the first electrode in the piezoelectric layer, as shown in FIG. 14 showing the results of the SIMS measurement.

Compared with the SIMS measurement results of Example 2 and Comparative Example 6, as shown in FIG. 13, in Example 2, lithium segregation is not present directly above the first electrode and the maximum value of the measured intensity (CPS) in the SIMS measurement of lithium was 1.71 times the minimum value. In addition, in Example 2, it was confirmed that lithium segregated in the vicinity of the insulating film in the first electrode.

On the other hand, as shown in FIG. 14, in Comparative Example 6, segregation of lithium was observed in the vicinity of the first electrode in the piezoelectric layer, and the maximum value of the measured intensity (CPS) in SIMS measurement was 2.65 times the minimum value.

The reason why the segregation state of lithium is different is considered to be due to the difference in heating rate of heating during crystallization of the piezoelectric layer in this case. It is considered that, if the temperature is raised relatively slowly, the elements crystallize in order starting with the one with the lowest crystallization temperature and are easily segregated, but if the heating rate is increased, the difference in crystallization temperature has less influence, and segregation becomes difficult.

### Other Embodiments

A description was given above of an embodiment of a piezoelectric material, a piezoelectric element, a liquid ejecting head, and a liquid ejecting apparatus on which the piezoelectric element is mounted of the invention; however, the basic configuration of the invention is not limited to the above description. For example, in the first embodiment described above, a silicon single crystal substrate is exemplified as the flow path forming substrate 10, but the invention is not limited thereto, and for example, a material such as an SOI substrate or glass may be used.

In the first embodiment described above, the description was given of an ink jet recording head as a liquid ejecting head; however, the invention is broadly applicable to liquid ejecting heads in general and application is naturally possible to a liquid ejecting head which ejects a liquid other than ink. Examples of other liquid ejecting heads include various recording heads used in image recording apparatuses such as printers, color material ejecting heads used in the manufacturing of color filters such as liquid crystal displays, organic EL displays, electrode material ejecting heads used when forming electrodes such as field emission displays (FED), bio-material ejecting heads used in biochip manufacturing, and the like.

In addition, the invention is not limited to a piezoelectric element mounted on a liquid ejecting head, and application is also possible to a piezoelectric element mounted on another piezoelectric element application device. Examples of piezoelectric element application devices include ultrasonic devices, motors, pressure sensors, pyroelectric element, ferroelectric elements, and the like. In addition, the piezoelectric element application devices also include completed objects utilizing these piezoelectric element application devices, for example, an apparatus ejecting liquid or the like using the head ejecting liquid or the like described above, an ultrasound sensor using the ultrasonic device described above, a robot where the motor described above is used as the driving source, an IR sensor using the pyroelectric element described above, a ferroelectric memory using a ferroelectric element, and the like.

The constituent elements shown in the drawings, that is, the thicknesses, widths, relative positional relationships and the like of the layers or the like may be enlarged in order to illustrate the invention. In addition, the term “on” in the present specification is not limited to meaning that the positional relationship of the constituent elements is “directly on”. For example, the expressions “first electrode on the substrate” and “piezoelectric layer on the first electrode” do not exclude other constituent elements from being included between the substrate and the first electrode or between the first electrode and the piezoelectric layer.

What is claimed is:

1. A piezoelectric element comprising:
a first electrode;
a piezoelectric layer which is a thin film formed on the first electrode and which is formed of a perovskite-type composite oxide including potassium, sodium, and niobium; and
a second electrode provided on the piezoelectric layer,
wherein the composite oxide further includes lithium and maximum value of a lithium measured intensity (CPS) in a film thickness direction of the piezoelectric layer in SIMS measurement is less than 2.65 times a minimum value.

2. The piezoelectric element according to claim 1,
wherein a content of lithium is 3 mol % to 5 mol % in a total number of moles of metal at the A site.

3. The piezoelectric element according to claim 1,
wherein the composite oxide further includes manganese, a content of manganese is 5 mol % or less in a total number of moles of metal at the B site.

4. The piezoelectric element according to claim 3,
wherein a content of manganese is 0.3 mol % to 2 mol % in a total number of moles of metal at the B site.

5. The piezoelectric element according to claim 1,
wherein the first electrode and the second electrode include at least one type of iridium and platinum, and are formed of a single layer or a plurality of layers.

6. The piezoelectric element according to claim 1,
wherein the first electrode is provided on a zirconium oxide layer, and the lithium in the piezoelectric layer is segregated on the zirconium oxide layer.

7. A piezoelectric element application device comprising:
the piezoelectric element according to claim 1.

8. A piezoelectric element application device comprising:
the piezoelectric element according to claim 2.

9. A piezoelectric element application device comprising:
the piezoelectric element according to claim 3.

10. A piezoelectric element application device comprising:
the piezoelectric element according to claim 4.

11. A piezoelectric element application device comprising:
the piezoelectric element according to claim 5.

12. A piezoelectric element application device comprising:
the piezoelectric element according to claim 6.

13. A method for manufacturing a piezoelectric element provided with a first electrode formed on a substrate, a piezoelectric layer formed of a perovskite-type composite oxide on the first electrode, and a second electrode formed on the piezoelectric layer, the method comprising:
forming a thin film of a piezoelectric layer including potassium, sodium, niobium, and lithium, on the first electrode,
wherein a piezoelectric layer in which a maximum value of a measured intensity (CPS) of lithium in a film thickness direction of the piezoelectric layer in SIMS measurement is less than 2.65 times a minimum value is obtained.
